(19) United States
(12) Patent Application Publication
(10) Pub. No.: US 2024/0194759 A1
(43) Pub. Date: Jun. 13, 2024

(54) FIELD EFFECT TRANSISTOR

(71) Applicant: ROHM CO., LTD., Kyoto-Shi (JP)

(72) Inventor: Manabu YANAGIHARA, Kyoto-Shi (JP)

(73) Assignee: ROHM CO., LTD., Kyoto-Shi (JP)

(21) Appl. No.: 18/530,334

(22) Filed: Dec. 6, 2023

(30) Foreign Application Priority Data
Dec. 8, 2022 (JP) 2022-196315

(51) Int. Cl. H01L 29/47; H01L 29/20; H01L 29/778

(52) U.S. Cl. CPC H01L 29/475; H01L 29/2003; H01L 29/7786

(57) ABSTRACT

The present disclosure provides a field effect transistor. The field effect transistor includes: an electron transport layer; an electron supply layer disposed on the electron transport layer; a plurality of source electrodes, a plurality of drain electrodes and a plurality of gate structures disposed on the electron supply layer. Each gate structure includes a gate layer and a gate electrode disposed on the gate layer. The field effect transistor further includes: a first high resistance region, a plurality of gate connection portions, a gate wiring and an insulating layer. The first high resistance region is disposed in the electron transport layer and the electron supply layer at a position between the drain electrodes adjacent to each other along an X direction. The gate connection portions electrically connect gate structures adjacent to each other along the X direction. The gate wiring is located above the first high resistance region.

### CROSS-REFERENCE TO RELATED APPLICATION

This application is based upon and claims the benefit of priority from Japanese Patent Application No. 2022-196315, filed on Dec. 8, 2022, the entire contents of which are incorporated herein by reference.

### TECHNICAL FIELD

The present disclosure relates to a field effect transistor.

### BACKGROUND

Currently, the commercialization of high electron mobility transistors (HEMT) employing group III nitride (such as gallium nitride (GaN)) semiconductor field effect transistors (FET) continues to develop. A HEMT uses a two-dimensional electron gas (2DEG) formed near an interface of a semiconductor heterojunction as a conductive path (channel) (for example, refer to patent publication 1). Comparing with typical Si power transistors, power transistors employing HEMTs are considered to be capable of low on-resistance and high-speed, high-frequency operations.

### PRIOR ART DOCUMENT

### Patent Publication

[Patent document 1] Japan Patent Publication No. 2017-73506

### BRIEF DESCRIPTION OF THE DRAWINGS

FIG. 1 is a brief plan view of an example of a field effect transistor according to a first embodiment.

FIG. 2 is an enlarged partial plan view of the field effect transistor in FIG. 1.

FIG. 3 is a schematic cross-sectional view along line F3-F3 in FIG. 2.

FIG. 4 is a schematic cross-sectional view along line F4-F4 in FIG. 1.

FIG. 5 is a schematic cross-sectional view along line F5-F5 in FIG. 2.

FIG. 6 is a brief plan view of an example of a field effect transistor according to a second embodiment.

FIG. 7 is an enlarged partial plan view of the field effect transistor in FIG. 6.

FIG. 8 is a schematic cross-sectional view along line F8-F8 in FIG. 7.

FIG. 9 is a schematic cross-sectional view along line F9-F9 in FIG. 6.

FIG. 10 is a schematic cross-sectional view along line F10-F10 in FIG. 7.

FIG. 11 is an enlarged partial plan view of the field effect transistor of a first application example.

FIG. 12 is an enlarged partial plan view of the field effect transistor of a second application example.

FIG. 13 is an enlarged partial plan view of the field effect transistor of a second application example.

### DETAILED DESCRIPTION OF THE EMBODIMENTS

Details of several embodiments of a field effect transistor of the present disclosure are given with the accompanying drawings below. Moreover, for better understanding and clarity, the constituting elements shown in the drawings may be partially enlarged and are not necessarily drawn to fixed scales. Moreover, for better understanding, shading lines may be omitted from the section views, and shading lines may be used to represent constituting elements. It should be noted that the accompanying drawings are for illustrating the embodiments of the present disclosure, and are not to be construed as limitations to the present disclosure.

The description below includes details for implementing a device a system and a method of the exemplary embodiments of the present disclosure. The detailed description is intended for illustration purposes and is not to be construed as limitations to the embodiments of the present disclosure or applications or uses of these embodiments.

### FIRST EMBODIMENT

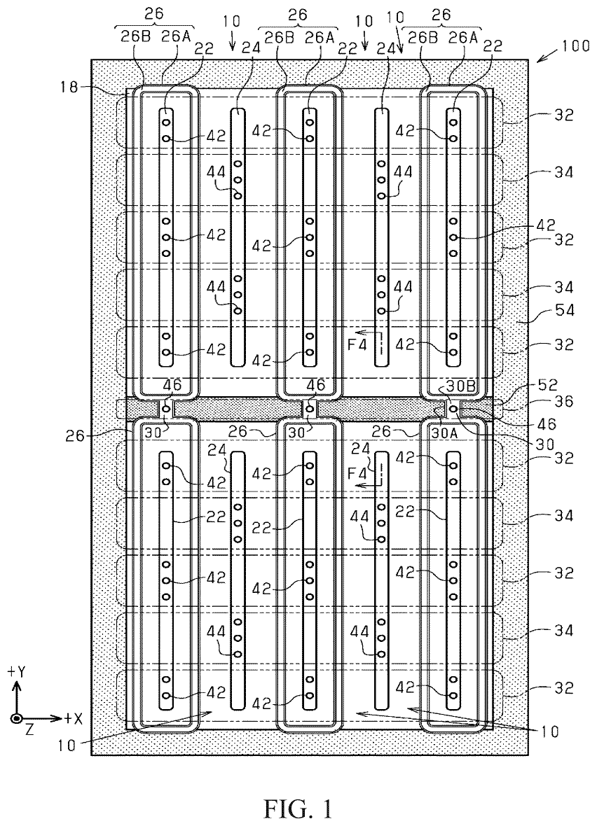

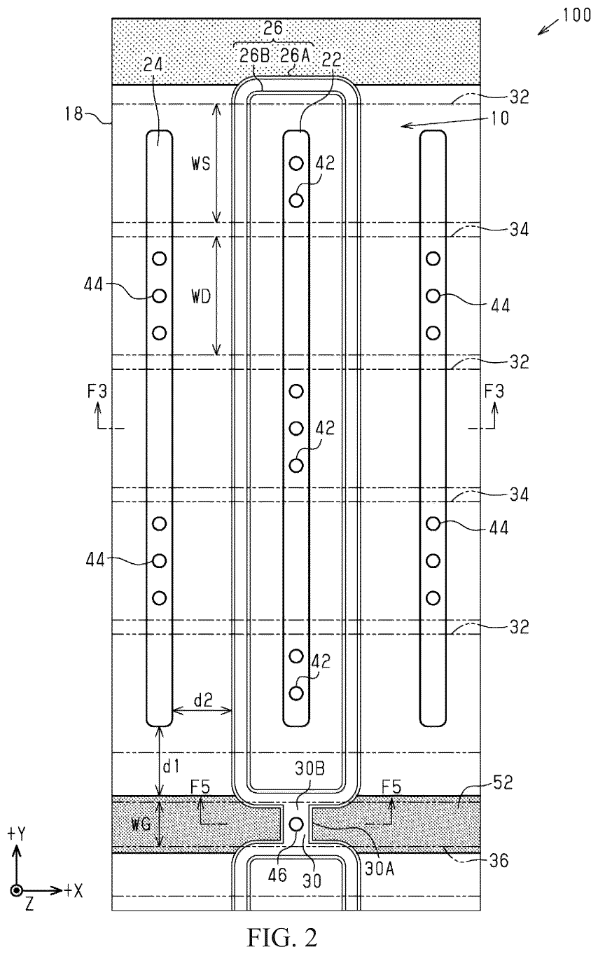

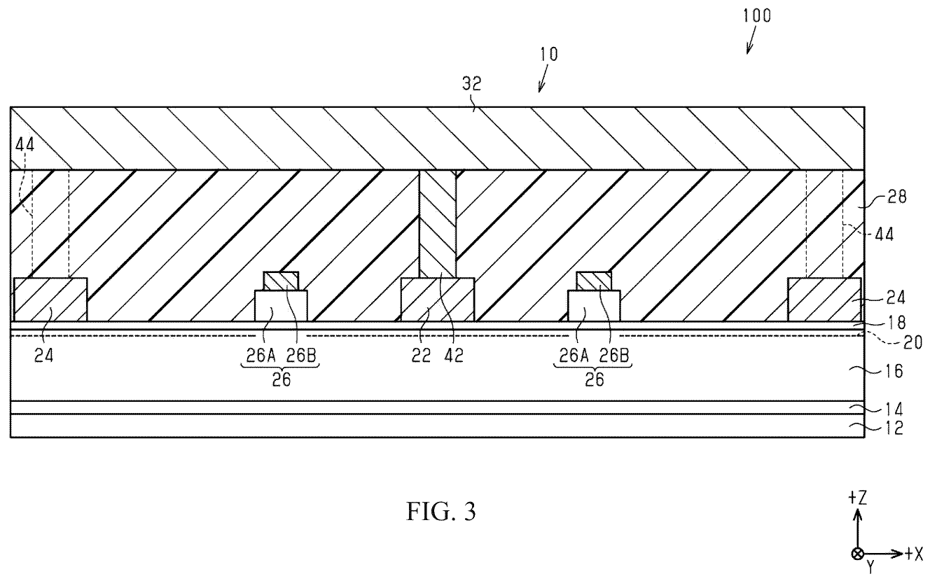

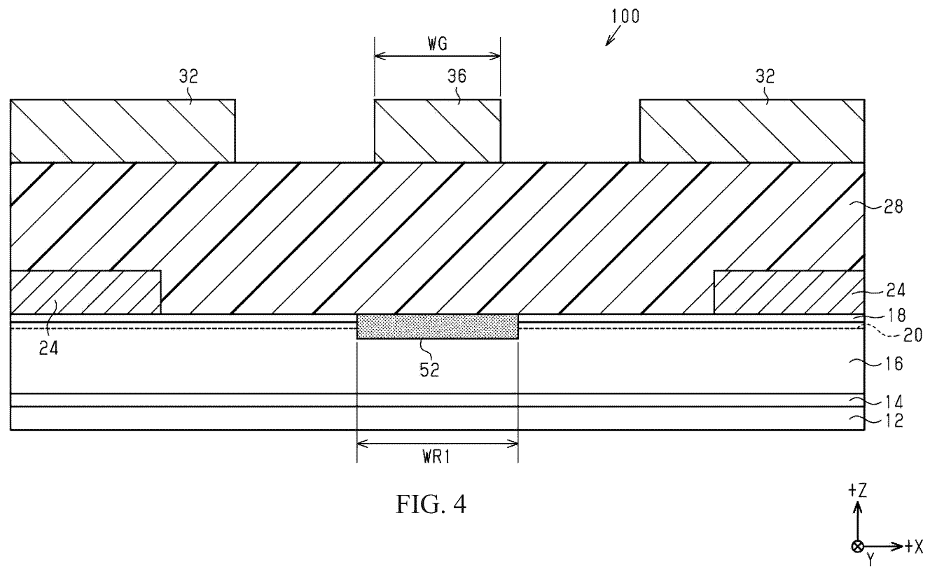

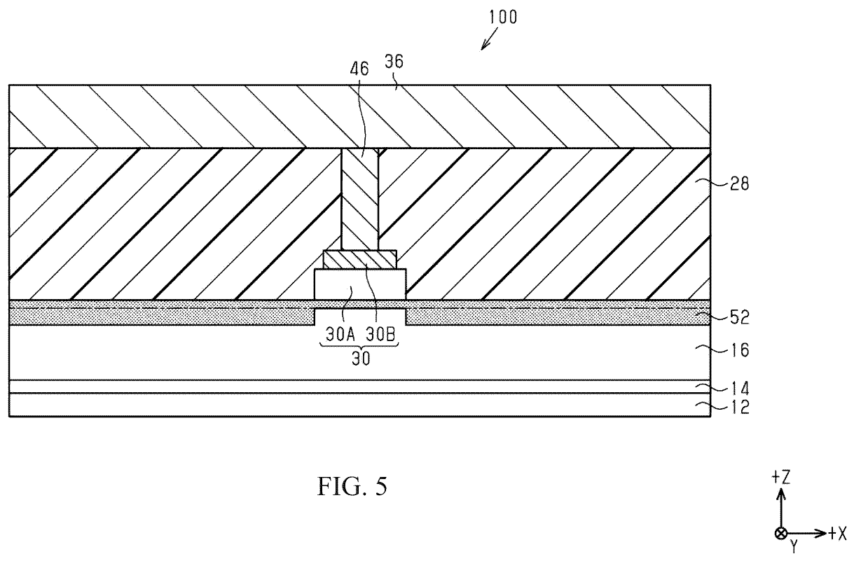

Referring to FIG. 1 to FIG. 5, a field effect transistor 100 according to the first embodiment is described below. FIG. 1 shows a brief plan view of the field effect transistor 100. FIG. 2 shows an enlarged partial plan view of the field effect transistor 100 in FIG. 1. FIG. 3 shows a schematic cross-sectional view along line F3-F3 in FIG. 2. FIG. 4 shows a schematic cross-sectional view along line F4-F4 in FIG. 1. FIG. 5 shows a schematic cross-sectional view along line F5-F5 in FIG. 2.

The field effect transistor 100 can be configured as a high electron mobility transistor (HEMT) employing a nitride semiconductor. A representing example of a nitride semiconductor is such as gallium nitride (GaN), aluminum nitride (AlN) or indium nitride (InN), and can usually be represented as AlₓIn_{y}Ga_{1-x-y}N(0≤x≤1, 0≤y≤1, 0≤x+y≤1).

Moreover, the expression “in a plan view” used in the present disclosure, unless otherwise specified, refers to observing a target (the field effect transistor 100 or the constituting element) in a Z direction with X-axis, Y-axis and Z-axis being perpendicular to one another, as shown in the drawings. Moreover, the Y direction is sometimes referred to as a first direction and the X direction is sometimes referred to as a second direction below. Moreover, for better understanding, the +Z direction is sometimes referred to as up, the −Z direction is sometimes referred to as down, the +X direction is sometimes referred to as right, and the −X direction is sometimes referred to as left.

### 1-1. Exemplary Cross-Sectional Structure of HEMT

As shown in FIG. 1 and FIG. 2, the field effect transistor 100 includes multiple transistors 10 each having a HEMT structure employing a nitride semiconductor. First of all, the HEMT structure of the unit transistor 10 is described in brief with reference to the section diagram of FIG. 3.

FIG. 3 shows an exemplary schematic cross-sectional view of the unit transistor 10 having a HEMT structure. The HEMT structure of each unit transistor 10 is the same as that of another. The HEMT structure is described by focusing on one unit transistor 10; however, the description given is applicable to other unit transistors 10.

The unit transistor 10 (the field effect transistor 100) includes a substrate 12, a buffer layer 14 formed on the substrate 12, an electron transport layer 16 formed on the buffer layer 14, and an electron supply layer 18 formed on the electron transport layer 16. The substrate 12 can be formed of, for example, silicon (Si), silicon carbide (SiC), GaA, sapphire, or other substrate materials. For example, the substrate 12 is a conductive Si substrate. A thickness of the substrate 12 can be, for example, between about 200 micrometers (μm) and about 1500 μm. Moreover, the Z direction shown in the drawings is a direction perpendicular to a main surface of the substrate 12.

The buffer layer 14 is located between the substrate 12 and the electron transport layer 16, and is formed of any material capable of inhibiting die warping or cracking caused by mismatch between thermal expansion coefficients of the substrate 12 and the electron transport layer 16. For example, the buffer layer 14 can include one or more nitride semiconductor layers. For example, the buffer layer 14 can include at least one of an aluminum nitride (AlN) layer, aluminum gallium nitride (AlGaN) layer, and a graded AlGaN layer with a continuously varying composition of aluminum (Al). For example, the buffer layer 14 can be formed by one single AlN layer, one single AlGaN layer, a layer having an AlGaN/GaN superlattice structure, a layer having an AlN/AlGaN superlattice structure, a layer having an AlN/GaN superlattice structure, or a combination of two or more of the above layers.

In one example, the buffer layer 14 includes a first buffer layer formed on the substrate 12, and a second buffer layer formed on the first buffer layer. The first buffer layer is, for example, an AlN layer, and has a film thickness of, for example, 200 nm. The second buffer layer, for example, includes multiple AlGaN layers, each of which can have a thickness of approximately 100 nm. Moreover, to suppress a leakage current in the buffer layer 14, an impurity can be introduced to a part of the buffer layer 14 so as to become semi-insulative. In this case, the impurity is, for example, carbon (C) or iron (Fe), and can have a concentration set to 4×10¹⁶ cm⁻³ or more.

The electron transport layer 16 can be formed of a nitride semiconductor. The electron transport layer 16 corresponds to the first nitride semiconductor layer. For example, the electron transport layer 16 can be a GaN layer. A thickness of the substrate 16 can be, for example, between about 0.1 μm and about 2 μm. Moreover, to suppress a leakage current in the electron transport layer 16, an impurity can also be introduced to a part of the buffer layer 16 such that a region other than a surface-layer region of the electron transport layer 16 set to be semi-insulative. In this case, the impurity is, for example, carbon (C), and can have a concentration set to 1×10¹⁹ cm⁻³ or more.

The electron supply layer 18 can be formed of a nitride semiconductor. The electron supply layer 18 corresponds to the second nitride semiconductor layer. For example, the electron supply layer 18 can be an AlGaN layer. A bandgap gets larger as the Al composition increases in the AlGaN layer. Thus, the electron supply layer 18 which is an AlGaN layer has a bandgap greater than that of the electron transport layer 16. For example, the electron supply layer 18 is made of AlₓGa₁₋ₓN, where x is, for example but not limited to, within a range of 0<x<0.4, and more preferably 0.2<x<0.3. A thickness of the electron supply layer 18 can be, for example, between about 5 μm and about 20 μm.

The electron transport layer 16 and the electron supply layer 18 are made of nitride semiconductors having different lattice constants from each other. Thus, the nitride semiconductor (for example, GaN) forming the electron transport layer 16 and the nitride semiconductor (for example, AlGaN) forming the electron supply layer become a joint of a lattice mismatched system. With spontaneous polarization of the electron transport layer 16 and the electron supply layer 18 as well as piezoelectric polarization caused by stress upon a heterojunction of the electron supply layer 18, a conduction band energy level of the electron transport layer 16 near the heterojunction interface between the electron transport layer 16 and the electron supply layer 18 is lower than a Fermi level. Thus, at a position near the heterojunction interface the electron transport layer 16 and the electron supply layer 18 (for example, a position distanced from the interface by approximately several nm), a two-dimensional electron gas (2DEG) 20 is diffused into the electron transport layer 16.

The unit transistor 10 (the field effect transistor 100) further includes a source electrode 22, a drain electrode 24 and a gate structure 26 disposed on the electron supply layer 18, and an insulating layer 28 covering the source electrode 22, the drain electrode 24 and the gate structure 26. The insulating layer 28 is formed by any one single film of a silicon nitride (SiN) film, a silicon oxide (SiO₂) film, a silicon oxynitride (SiON) film, an aluminum oxide (Al₂O₃) film, an AlN film and an aluminum oxynitride (AlON) film, or a composite film formed by a combination including two or more of the above.

The source electrode 22 and the drain electrode 24 are in ohmic contact with the 2DEG 20 directly below the electron supply layer 18 and in the electron transport layer 16, that is, electrically connected to the 2DEG 20. The source electrode 22 and the drain electrode 24 can be formed by, for example, one or more metal layers implemented by at least one of a titanium (Ti) layer, a titanium nitride (TiN) layer, an Al layer, an aluminum silicon copper (AlSiCu) layer and an aluminum copper (AlCu) layer. The source electrode 22 and the drain electrode 24 are formed of the same metal material. The source electrode 22 and the drain electrode 24 can also be formed of different metal materials.

The gate structure 26 includes a gate layer 26A disposed on the electron supply layer 18, and a gate electrode 26B disposed on the gate layer 26A. The gate layer 26A can be formed of a nitride semiconductor having a bandgap smaller than that of the electron supply layer 18. The gate layer 26A corresponds to a third nitride semiconductor layer. For example, when the electron supply layer 18 is an AlGaN layer, the gate layer 26A can be a GaN layer doped with an acceptor type impurity, that is, a p-type GaN layer. The acceptor type impurity can include at least one of zinc (Zn), manganese (Mg) and carbon (C). A maximum concentration of the acceptor type impurity in the gate layer 26A is, for example, 7×10¹⁸ cm⁻³ or more and 1×10²⁰ cm⁻³ or less.

A thickness of the gate layer 26A is not specifically defined, and can be appropriately determined with consideration of various parameters such as a gate withstand voltage. For example, the thickness of the gate layer 26A can be, for example, between about 80 μm and about 150 μm. Moreover, a cross-sectional shape of the gate layer 26A along the ZX plane in FIG. 3 is not specifically defined, and can be, for example, a rectangular shape, a trapezoidal shape, a ridged shape or any other shape as desired.

The gate electrode 26B is formed by one or more metal layers. The gate electrode 26B and the gate layer 26A form a Schottky junction or an ohmic contact. For example, in case of a Schottky junction, the gate electrode 26B can be formed by employing at least one of a TiN layer, a tungsten silicon (WSi) layer, and a tungsten silicon nitride (WSiN) layer. Since these metals including TiN, WSi and WSiN are high melting point metals, microfabrication to obtain a desired gate electrode length can be relatively easily performed by means of dry etching. Moreover, in case of a Schottky junction, since a gate current almost does not flow, a power transistor employing a HEMT can be easily driven. A thickness of the gate layer 26B can be, for example, between about 50 μm and about 300 μm.

The gate electrode 26B can have a width less than or equal to that of the gate layer 26A along the X direction. Such gate structure 26 is beneficial in terms of reducing a gate leakage current compared to a case where the gate electrode 26B is formed to have a same width as the gate layer 26A along the X direction. However, the gate electrode 26B can also be formed to have a same width as the gate layer 26A.

In case where the gate layer 26A is formed by a nitride semiconductor including an acceptor type impurity, when a zero bias voltage is not applied to the gate electrode 26B, the 2DEG 20 in the region directly below gate layer 26A is depleted such that a conductive path (a channel) is cut off. Accordingly, a normally off HEMT having a positive threshold voltage is implemented.

### 1-2. Exemplary Planar Layout of Field Effect Transistor

Next, primarily with reference to the plan views of FIG. 1 and FIG. 2 as well as with reference to the section diagrams of FIG. 3 to FIG. 5, an exemplary planar layout of the field effect transistor 100 is described. Moreover, for better understanding, the drawing of the insulating layer 28 is omitted from FIG. 1 and FIG. 2.

As shown in FIG. 1, the field effect transistor 100 includes multiple source electrodes 22 arranged along the Y direction (a first direction) and the X direction (a second direction) on the electron supply layer 18 in the plan view. In the example in FIG. 1, a total of six source electrodes are arranged in three rows along the X direction and in two columns along the Y direction. Each of the source electrodes 22 has an elongated strip shape extending along the Y direction.

Moreover, the field effect transistor 100 includes multiple drain electrodes 24 arranged along the Y direction and the X direction on the electron supply layer 18 in the plan view. In the example in FIG. 1, a total of four source electrodes are arranged in two rows along the X direction and in two columns along the Y direction. Each of the drain electrodes 24 has an elongated strip shape extending along the Y direction. The drain electrodes 24 are alternately arranged with the source electrodes 22 along the X direction. In this case, the source electrodes 22 but not the drain electrodes 24 can be located on both ends along the X direction. In the configuration above, compared to positions of the source electrodes 22, positions of the drain electrodes 24 applied with a voltage are in an outer peripheral region (a high resistance region to be described below) away from the field effect transistor 100 along the X direction. Thus, a leakage current from the drain electrodes 24 to the substrate 12 via the outer peripheral region (the high resistance region) can be reduced.

Moreover, the field effect transistor 100 includes multiple gate structures 26 arranged along the Y direction and the X direction on the electron supply layer 18 in the plan view. In the example in FIG. 1, a total of six gate structures 26 are arranged in three rows along the X direction and in two columns along the Y direction. Each of the gate structures 26 extends along the Y direction and surrounds one of the source electrodes 22 in the plan view. That is to say, each of the gate structures 26 is formed to have a loop shape.

Moreover, the term “a loop shape” used in the present disclosure refers to not only any structure having an endless continuous shape, that is, a loop shape, but further refers to a structure having a substantially loop shape with an incision (a gap) such as a C shape. Moreover, the term “an enclosed loop shape” specified refers to any structure formed to have an endless continuous shape, that is, a loop shape. On the other hand, the term “an open loop shape” specified refers to a structure having a substantially loop shape with an incision. In addition to an ellipsoidal shape, such “loop shape” further includes any shape including multiple corners, wherein the angles are right-angled corners or round-angled corners. In the example in FIG. 1, each of the gate structures 26 is formed to have an enclosed loop shape.

As described with reference to FIG. 3, each of gate structures 26 includes the gate layer 26A disposed on the electron supply layer 18, and a gate electrode 26B disposed on the gate layer 26A. Thus, each of the gate layers 26A and the gate electrodes 26B is also formed to have an enclosed loop shape. As such, since each of the source electrodes 22 is surrounded by one corresponding of the multiple gate structures 26, a leakage current between the source electrode 22 and the drain electrode 24 adjacent to each other is reduced.

Moreover, the gate structures 26 can also be used in substitution for structures that surround the source electrodes 22, and be modified to be structures surrounding the drain electrodes 24. However, to increase a withstand voltage of the field effect transistor 100, a gate-drain distance needs to be greater than a gate-source distance. Thus, when the gate structures 26 are structures that surround the drain electrodes 24, a distance between one drain electrode 24 and the gate structure 26 surrounding this drain electrode 24 is also increased, so that a chip area is increased compared to the structures that surround the source electrodes 22.

In the example in FIG. 1, the field effect transistor 100 includes a total of six unit transistors 10 arranged in three rows along the X direction and in two columns along the Y direction. Each of the unit transistors 10 includes the source electrode 22, the gate structure 26 (the gate layer 26A and the gate electrode 26B) surrounding the source electrode 22, and one drain electrode 24 adjacent to the gate structure 26 on one side along the X direction. Moreover, in the example in FIG. 1, the unit transistor 10 located at the center in the X direction and the unit transistor 10 located on the rightmost in the X direction share the drain electrode 24.

Moreover, FIG. 1 depicts six unit transistors 10 as an example; however, the number of the unit transistor 10 can be in a greater or smaller number. For example, in order to achieve desired on-resistance and current value for an FET used for power switching, the number of the unit transistor 10 can be increased along the X direction and/or the Y direction.

As shown in FIG. 1 and FIG. 2, the field effect transistor 100 includes gate connection portions 30 electrically connecting the adjacent gate structures 26 along the Y direction. In the example in FIG. 1, three gate connection portions 30 are disposed to correspond to the three gate structures 26 disposed in three rows along the X direction.

As shown in FIG. 5, similar to the gate structures 26, each of the gate connection portions 30 also includes a gate layer 30A and a gate electrode 30B. The gate layer 30A has a structure similar to that of the gate layer 26A (referring to FIG. 3) of the gate structure 26, and is formed integrally to be continuous with the gate layer 26A of the adjacent gate structure along the Y direction. Moreover, the gate electrode 30B has a structure similar to that of the gate electrode 26B (referring to FIG. 3) of the gate structure 26, and is formed integrally to be continuous with the gate electrode 26B of the adjacent gate structure along the Y direction.

The gate connection portions 30 can have, for example, a rectangular shape in the plan view. The gate electrode 30B of the gate connection portion 30 can have a width along the X direction greater than that of the gate electrode 26B of the gate structure 26 along the X direction. Moreover, the gate electrode 30B can have a width along the Y direction greater than that of the gate electrode 25B along the X direction. For example, the width of the gate electrode 26B along the X direction can be between about 0.5 μm and about 1.5 μm. With respect to the above, the width of the gate electrode 30 along each of the X direction and the Y direction can be between about 2 μm and about 5 μm.

Moreover, as shown in FIG. 5, similar to the gate structure 26, the gate electrode 30B in the gate connection portion 30 can have a width less than or equal to that of the gate layer 30A along the X direction. By providing the gate connection portions 30 to have a greater with than the gate structures 26, gate connection conductors to be described shortly can be easily arranged on the gate connection portions 30.

As shown in FIG. 1 and FIG. 2, the field effect transistor 100 includes multiple source wirings 32, multiple drain wirings 34 and a gate wiring 36. Moreover, for better understanding, in FIG. 1 and FIG. 2, double-dotted lines are used to represent an outer periphery of each of the source wirings 32, the drain wirings 34 and the gate wiring 36.

The source wirings 32, the drain wirings 34 and the gate wiring 36 are arranged on the insulating layer 28 (referring to FIG. 3 to FIG. 5). Thus, the source wirings 32, the drain wirings 34 and the gate wiring 36 are located in the same layer. The insulating layer 28 covers the source electrodes 22, the drain electrodes 24, the gate structures 26 and the gate connection portions 30. Thus, the source wirings 32, the drain wirings 34 and the gate wiring 36 are disposed in a different layer from the source electrodes 22, the drain electrodes 24, the gate structures 26 and the gate connection portions 30.

The source wirings 32, the drain wirings 34 and the gate wiring 36 can be formed of, for example, Au, Cu, Al or an alloy of Al and Cu. The source wirings 32, the drain wirings 34 and the gate wiring 36 can be formed of, for example, a same material simultaneously.

The source wirings 32 are disposed in a region in which the source electrodes 22 are disposed along the X direction to extend along the X direction, and are electrically connected to the source electrodes 22 via multiple source connection conductors 42 passing through the insulating layer 28. Similarly, the drain wirings 34 extend throughout a region where the drain electrode 24 are disposed along the X direction to extend along the X direction, and are electrically connected to the drain electrodes 24 via a multiple drain connection conductors 44 passing through the insulating layer 28.

The source wirings 32 are alternately arranged with the drain wirings 34 with each other along the Y direction. In the examples shown in FIG. 1 and FIG. 2, three source wirings 32 and two drain wirings 34 are alternately arranged with each other throughout an extension region of the source electrodes 22 and the drain electrodes 24 along the Y direction. However, the number of the source wirings 32 and the number of the drain wirings 34 are not specifically defined, and can be greater or smaller numbers.

Moreover, in the examples in FIG. 1 and FIG. 2, two source connection conductors 42 are disposed at both end portions of each of the source electrodes 22, and three source connection conductors 42 are disposed at the center portion of each of the source electrodes 22. The reason for the above is because a density of a current flowing in the source wirings 32 connected to the both end portions of each of the source electrodes 22 is smaller. However, the number of the source connection conductors 42 connecting each of the source wirings 32 and each of the source connection conductors 42 can also be a same number.

The gate wiring 36 extends throughout a region where the gate connection portions 30 are disposed along the X direction to extend along the X direction, and is electrically connected to the gate electrodes 30B of the gate connection portions 30 (referring to FIG. 5) via one or more (one in the example in FIG. 1 and FIG. 2) gate connection conductors 46 passing through the insulating layer 28. As described above, because the gate electrode 30B of the gate connection portion 30 is integrally formed to be continuous with the gate electrode 26B of the gate structure 26, the gate wiring 36 is electrically connected with the gate electrode 26B of the gate structure 26.

The source connection conductors 42, the drain connection conductors 44 and the gate connection conductors 46 can be formed as plugs by a metal material such as tungsten (W). Alternatively, the source connection conductors 42, the drain connection conductors 44 and the gate connection conductors 46 can also be implemented by the same wiring material as the source wirings 32, the drain wirings 34 and the gate wiring 36, so as to serve as channels embedded into the insulating layer 28. Each of the source connection conductors 42, the drain connection conductors 44 and the gate connection conductors 46 can have a diameter of between about 0.8 μm and about 2 μm.

The gate wiring 36 is disposed between two source wirings 32 along the Y direction. In other words, the gate wiring 36 is adjacent to the source wirings 32 in the Y direction. With the configuration above, compared to when the gate wiring 36 is adjacent to the drain wirings 34, a gate-drain parasitic capacitance is reduced.

Moreover, as shown in FIG. 2, a wiring width WG of the gate wiring 36 is less than or equal to a wiring width WS of the source wirings 32, and is less than or equal to a wiring width WD of the drain wirings 34. Moreover, the wiring widths WG, WS and WD refer to respective sizes along the Y direction. With the configuration above, a gate-drain parasitic capacitance and a gate-source parasitic capacitance dependent on an area of the gate wiring 36 are reduced.

As shown in FIG. 1 and FIG. 2, the field effect transistor 100 includes a first high resistance region 52 located between the adjacent drain electrodes 24 along the Y direction. As shown in FIG. 4 and FIG. 5, the first high resistance region 52 is formed at a depth from an upper surface position of the electron supply layer 18 to a position beyond a channel region of the 2DEG 20 formed in the electron transport layer 16. Thus, the first high resistance region 52 is formed to cross both the electron supply layer 18 and the electron transport layer 16. The first high resistance region 52 functions to electrically isolate the 2DEG 20 having equal potential as the drain electrode 24, that is, functions to cut off a conduction of the 2DEG 20 at a position between adjacent drain electrodes 24 along the Y direction.

As shown in FIG. 1, the first high resistance region 52 can be formed to be continuous along the X direction, for example. Thus, the gate wiring 36 is disposed above the first high resistance region 52 with the insulating layer 28 (referring to FIG. 4) separating in between in the plan view. Moreover, as shown in FIG. 4, the first high resistance layer 52 can be formed to have, for example, a width WR1 greater than the wiring width WG of the gate wiring 36 along the Y direction. In other words, the wiring width WG of the gate wiring 36 is set to be less than or equal to the width WR1 of the first high resistance region 52 by a manner that the gate wiring 36 is formed within a range of the first high resistance region 52 without going beyond the first high resistance region 52 along the Y direction.

The first high resistance region 52 is a region in which the 2DEG 20 substantially disappears, and is a region in which a sheet resistance is higher than a channel area where 2DEG 20 exists by more than 3 bits. The first high resistance region 52 includes an impurity that forms a region having a higher resistance than that of the channel region of the 2DEG 20. For example, the first high resistance region 52 includes an impurity introduced by ion implantation. With the ion implantation, compared to when the first high resistance region 52 is formed by removing a channel region by means of etching, flatness of an upper surface of the electron supply layer 18 can be maintained and the first high resistance region 52 can be well formed.

When ion implantation is used, the ion species (the impurity) can be at least one of helium (He), boron (B), nitrogen (N), oxygen (O), fluorine (F) and argon (Ar). For example, the first high resistance region 52 can be formed by sequentially laminating a first nitride semiconductor layer forming the electron transport layer 16, a second nitride semiconductor layer forming the electron supply layer 18 and a third nitride semiconductor layer forming the gate layer 26A by means of epitaxial growth, and then performing ion implantation on the first and second nitride semiconductor layers via the third nitride semiconductor layer. In this case, since the ion species is relatively light element, the ion species is allowed to reach a region of the electron transport layer 16 (the first nitride semiconductor layer) forming the 2DEG 20 to further form the first high resistance region 52 even if ion implantation is performed via the third nitride semiconductor layer.

During the operation of the field effect transistor 100, the 2DEG 20 in a region directly below the drain electrode 24 becomes equal potential as the drain electrode 24. Thus, when the first high resistance region 52 is not provided, the 2DEG 20 in a region directly below adjacent drain electrodes 24 along the Y direction also becomes equal potential as the drain electrode 24. As a result, a gate-drain parasitic capacitance formed between the 2DEG 20 having equal potential as the drain electrode 24 is increased.

With respect to the above, with the first high resistance region 52 located between adjacent drain electrodes 24 along the Y direction, the 2DEG 20 having equal potential as the drain electrode 24 is electrically isolated at a position of the first high resistance region 52. As a result, the gate-drain parasitic capacitance formed between the gate wiring 36 and the 2DEG 20 having equal potential as the drain electrode 24 is reduced. In this case, the wiring width WG of the gate wiring 36 is particularly set to be less than or equal to the width WR1 of the first high resistance value 52, and so the gate wiring 36 does not go beyond the first high resistance region 52 along the Y direction. Thus, the gate-drain parasitic capacitance is significantly reduced.

As shown in FIG. 1 and FIG. 2, the field effect transistor 100 further includes a second high resistance region 54 surrounding the multiple electrodes 22, the multiple drain electrodes 24 and the multiple gate structures 26 in the plan view. For example, the second high resistance region 54 can be formed to have a loop shape in an outer peripheral region (for example, along an outer periphery) of the field effect transistor 100. Although a detailed section diagram is omitted, similar to the first high resistance region 52 (FIG. 4 and FIG. 5), the second high resistance region 54 is also formed to cross both the electron supply layer 18 and the electron transport layer 16. For example, the first high resistance region 52 and the second high resistance region 54 can be formed simultaneously.

Similar to the first high resistance region 52, the second high resistance region 54 is a region in which the 2DEG 20 substantially disappears, and is a region in which a sheet resistance is higher than the channel area where 2DEG 20 exists by more than 3 bits. The second high resistance region 54 also includes an impurity that forms a region having a higher resistance than that of the channel region of the 2DEG 20. For example, the second high resistance region 54 includes an impurity introduced by ion implantation. With the ion implantation, compared to when the second high resistance region 54 is formed by removing a channel region by means of etching, flatness of an upper surface of the electron supply layer 18 can be maintained and the second high resistance region 54 can be well formed.

By forming the second high resistance region 54 to have a loop shape in the outer peripheral region of the field effect transistor 100, an entire element forming region in which multiple (six in the example in FIG. 1) unit transistors 10 are formed is surrounded by the second high resistance region 54. Accordingly, a drain-source leakage current and a drain-gate leakage current are inhibited from flowing to the outer peripheral region of the field effect transistor 100 via the 2DEG 20.

Moreover, in the example in FIG. 1, the first high resistance region 52 is connected to the second high resistance region 54. Thus, the multiple (three in the example in FIG. 1) unit transistors 10 arranged along the X direction are surrounded by the first high resistance region 52 and the second high resistance region 54. Accordingly, since a region of the 2DEG 20 having equal potential as the drain electrode 24 is disconnected in the element forming region, the drain-source leakage current and the drain-gate leakage current via the 2DEG 20 are inhibited.

Moreover, in the example in FIG. 1, each drain electrode 24 is surrounded by the first high resistance region 52 adjacent to one side along the Y direction, the second high resistance region 54 adjacent to the other side along the Y direction and the gate structure 26 adjacent to both sides along the X direction. Accordingly, since a region of the 2DEG 20 having equal potential as the drain electrode 24 is further disconnected in the element forming region, the drain-source leakage current and the drain-gate leakage current via the 2DEG 20 are further inhibited.

Moreover, when the unit transistors 10 are disposed in three or more rows along the Y direction, each drain electrode 24 disposed at other than the both ends of the field effect transistor 100 along the Y direction is surrounded by the first high resistance region 52 adjacent to both sides along the Y direction and the gate structures 26 adjacent to both sides along the X direction.

As shown in FIG. 2, the drain electrode 24 is separated by a distance d1 from the first high resistance region 52 along the Y direction. Moreover, the drain electrode 24 is separated by a distance d2 from the gate structure 26 along the X direction. In this case, the distance d1 can be set to be greater than the distance d2. In the configuration above, an electric field applied between the drain electrode 24 and the first high resistance region 52 is smaller than an electric field applied between the drain electrode 24 and the gate structure 26. Accordingly, a decrease in a gate-drain withstand voltage caused by an electric field generated between the drain electrode 24 and the first high resistance region 52 is inhibited.

### 1-3. Effects of Field Effect Transistor

During the operation of the field effect transistor 100, the 2DEG 20 in a region directly below the drain electrode 24 becomes equal potential as the drain electrode 24. The field effect transistor 100 includes the first high resistance region 52 located between the adjacent drain electrodes 24 along the Y direction. The first high resistance region 52 is a region in which the 2DEG 20 substantially disappears, and electrically isolates the 2DEG 20 having equal potential as the drain electrode 24. That is to say, the first high resistance region 52 cuts off a conduction of the 2DEG 20 at a position between adjacent drain electrodes 24 along the Y direction. Accordingly, a gate-drain parasitic capacitance formed between the gate wiring 36 located above the first high resistance region 52 and the 2DEG 20 having equal potential as the drain electrode 24 is reduced. More particularly, since the gate wiring 36 does not go beyond the first high resistance region 52 along the Y direction, the gate-drain parasitic capacitance is significantly reduced.

Moreover, the source wirings 32, the drain wirings 34 and the gate wiring 36 are disposed in a different layer from the source electrodes 22, the drain electrodes 24, and the gate electrodes 26B and 30B. Thus, the source wirings 32, the drain wirings 34 and the gate wiring 36 can be formed of a material difference from the material forming the source electrodes 22, the drain electrodes 24 and the gate electrodes 26B and 30B.

For example, to enable the gate layers 26A and 30A to form a Schottky junction, the gate electrodes 26B and 30B can be formed by employing at least one of TiN, WSi and WSiN. The high melting point metal has an advantage of promoting microprocessing (for forming the gate electrodes 26B and 30B). On the other hand, since the specific resistance of a high melting point metal is high, the wiring resistance becomes large when the high melting point metal is used as the material for forming the gate wiring 36. Thus, a high melting point metal is unsuitable in terms of serving as a wiring material for implementing high speed switching. In addition to the gate wiring 36, the same applies to the source wirings 32 and the drain wirings 34.

With respect to the above, a material different from the material forming the source electrodes 22, the drain electrodes 24, and the gate electrodes 26B and 30B can be selected to form the source wirings 32, the drain wirings 34 and the gate wiring 36. Thus, a metal with a smaller wiring resistance can be selected, for example, Au, Cu, Al or an alloy of Al and Cu is selected as the wiring material.

The field effect transistor 100 of the first embodiment provides the following advantages.

(1-1) The first high resistance region 52 is located between adjacent drain electrodes 24 along the Y direction. The first high resistance region 52 cuts off a conduction of the 2DEG 20 at a position between adjacent drain electrodes 24 along the Y direction. According to the configuration above, the gate-drain parasitic capacitance formed between the gate wiring 36 arranged above the first high resistance region 52 and the 2DEG 20 having equal potential as the drain electrode 24 is reduced. Accordingly, a HEMT capable of high speed switching with reduced switching loss can be implemented.

(1-2) The wiring width WG of the gate wiring 36 is set to be less than or equal to the width WR1 of the first high resistance region 52 by a manner that the gate wiring 36 does not go beyond the first high resistance region 52 along the Y direction. According to the configuration above, the gate-drain parasitic capacitance can be further reduced.

(1-3) The gate wiring 36 is disposed on the insulating layer 28. The insulating layer 28 covers the gate structures 26 and the gate connection portions 30. Thus, the gate wiring 36 is disposed in a different layer from the gate electrodes 26B of the gate structures 26 and the gate electrodes 30B of the gate connection portions 30. According to the configuration above, a material different from the material forming the electrodes 26B and 30B can be selected as a material for forming the gate wiring 36. For example, even when the gate electrodes 26B and 30B are formed by a high melting point metal having a larger specified resistance, the gate wiring 36 can formed by a metal having a smaller wiring resistance. Accordingly, the gate wiring resistance can be reduced to implement high speed switching.

(1-4) In the outer peripheral region of the field effect transistor 100, the second high resistance region 54 surrounding the multiple electrodes 22, the multiple drain electrodes 24 and the multiple gate structures 26 in the plan view is provided. According to the configuration above, since the element forming region is entirely surrounded by the second high resistance region 54, the drain-source leakage current and the drain-gate leakage current are inhibited from flowing to the outer peripheral region of the field effect transistor 100 via the 2DEG 20.

(1-5) The second high resistance 54 is connected to the first high resistance region 52. According to the configuration above, since a region of the 2DEG 20 having equal potential as the drain electrode 24 is disconnected in the element forming region, the drain-source leakage current and the drain-gate leakage current can be inhibited.

(1-6) Each drain electrode 24 is surrounded by the first high resistance region 52 adjacent to one side along the Y direction, the second high resistance region 54 adjacent to the other side along the Y direction and the gate structures 26 adjacent to both sides along the X direction. Moreover, when the unit transistors 10 are disposed in three or more rows along the Y direction, each drain electrode 24 disposed at other than the both ends of the field effect transistor 100 along the Y direction is surrounded by the first high resistance region 52 adjacent to both sides along the Y direction and the gate structures 26 adjacent to both sides along the X direction. According to the configuration above, since a region of the 2DEG 20 having equal potential as the drain electrode 24 is further disconnected in the element forming region, the drain-source leakage current and the drain-gate leakage current can be further inhibited.

(1-7) The distance d1 between the drain electrode 24 and the first high resistance region 52 along the Y direction is greater than the distance d2 between the drain electrode 24 and the gate structure 26 along the X direction. According to the configuration above, a decrease in the gate-drain withstand voltage caused by an electric field generated between the drain electrode 24 and the first high resistance region 52 can be inhibited.

(1-8) In addition to the gate wiring 36, the source wirings 32 and the drain wirings 34 are also arranged on the insulating layer 28. Since the insulating layer 28 covers the source electrodes 22 and the drain electrodes 24, the drain wirings 32 and the gate wiring 34 are disposed in a different layer from the source electrodes 22 and the drain electrodes 24. Thus, a material (for example, a same material as the gate wiring 36) different from the material forming the source electrodes 22 and the drain electrodes 24 can be selected as a material for forming the source wirings 32 and the drain wirings 34. Accordingly, wiring resistances of the source wirings 32 and the drain wirings 34 can be reduced.

(1-9) The gate wiring 36 is adjacent to the source wirings 32 along the Y direction. According to the configuration above, compared to when the gate wiring 36 is adjacent to the drain wirings 34, the gate-drain parasitic capacitance can be reduced.

(1-10) The wiring width WG of the gate wiring 36 is less than or equal to the wiring width WS of the source wirings 32, and is less than or equal to the wiring width WD of the drain wirings 34. According to the configuration above, the gate-drain parasitic capacitance and the gate-source parasitic capacitance dependent on the area of the gate wiring 36 can be reduced.

(1-11) The first and second high resistance regions 52 and 54 include impurities that form regions having a higher resistance than that of the channel region of the 2DEG 20, and are formed as regions in which the 2DEG 20 substantially disappears. For example, the first and second high resistance regions 52 and 54 include impurities introduced by ion implantation. With the ion implantation, compared to when the first and second high resistance regions 52 and 54 are formed by removing a channel region by means of etching, flatness of the upper surface of the electron supply layer 18 can be maintained and the first and second high resistance regions 52 and 54 can be well formed.

(1-12) The gate layer 26A of each gate structure 26 is formed by a nitride semiconductor including an acceptor-type impurity. According to the configuration above, each unit transistor 10 can be mounted as a normally-off HEMT.

(1-13) The gate electrode 26B of each gate structure 26 is formed of a metal that forms a Schottky junction with the gate layer 26A. In this case, for example, the gate electrode 26B can be formed by employing at least one of TiN, WSi and WSiN. The metal is a high melting point metal having a higher resistance. However, as described in (1-3), the gate wiring 36 can be formed of a different metal, and so an increase in the gate wiring resistance can be inhibited.

### SECOND EMBODIMENT

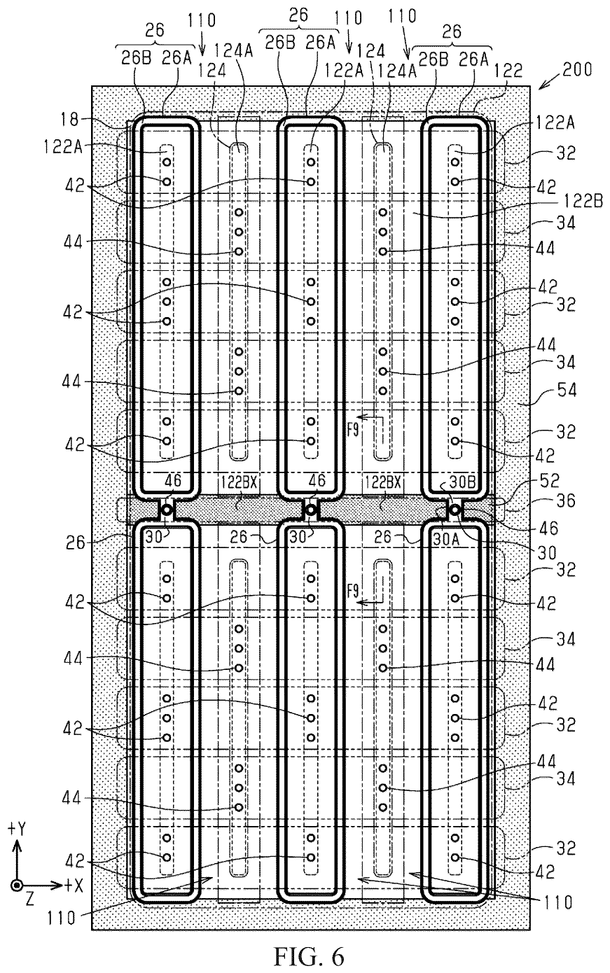

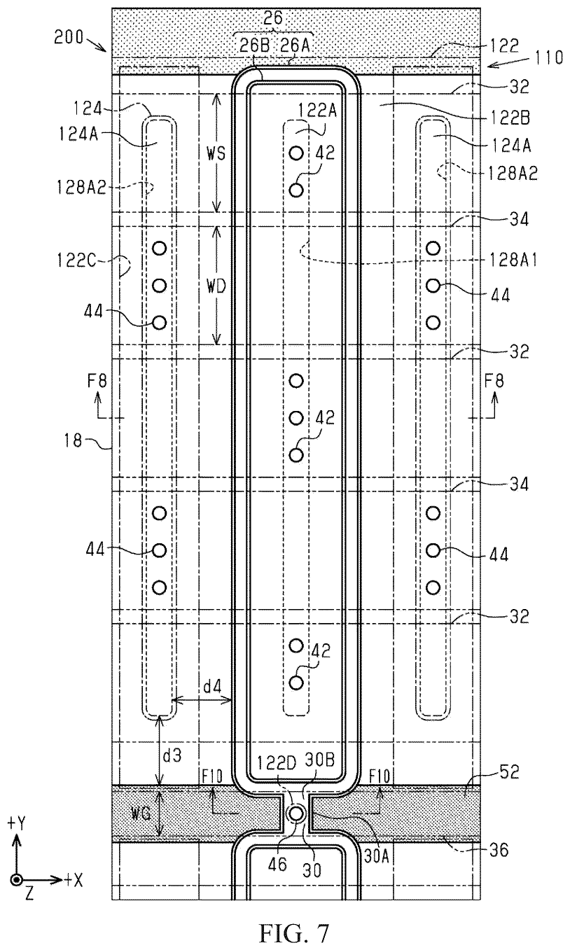

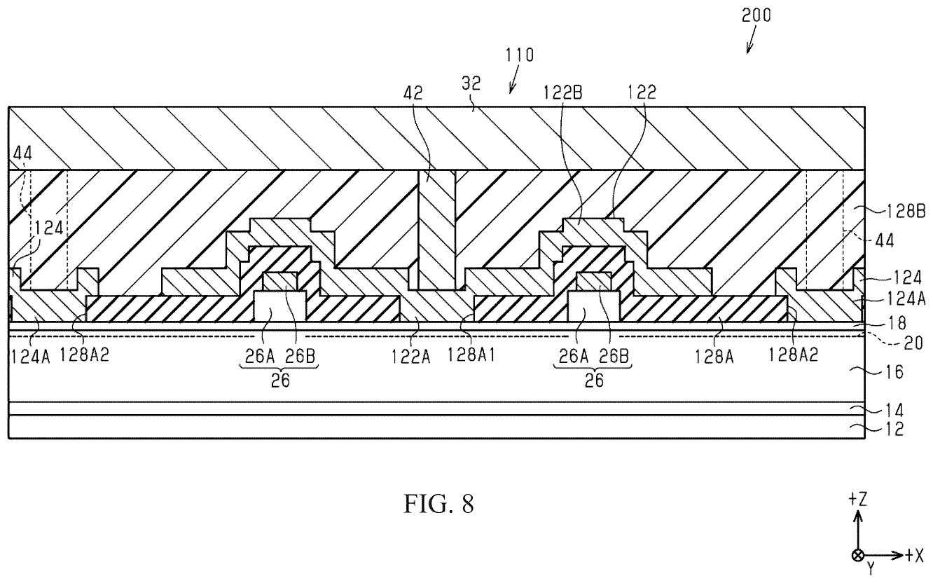

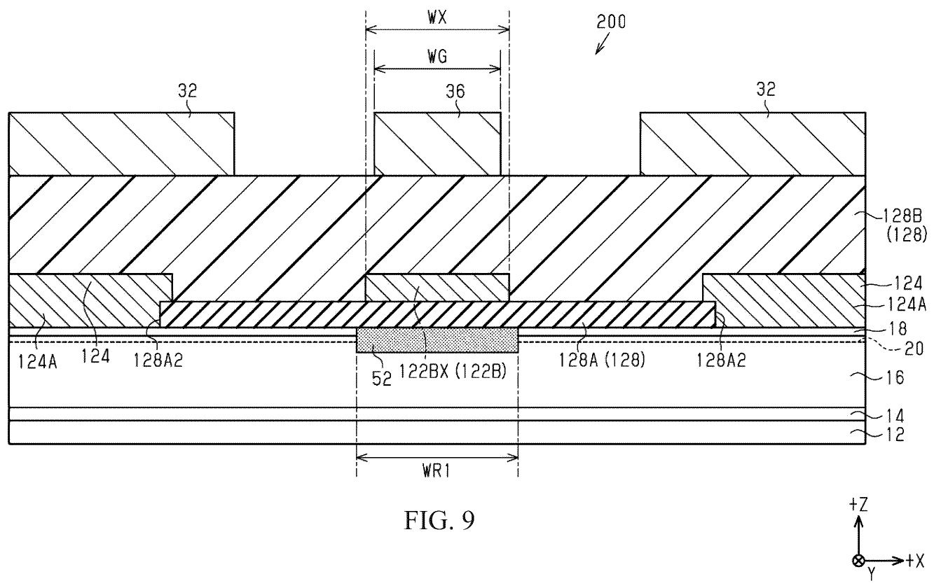

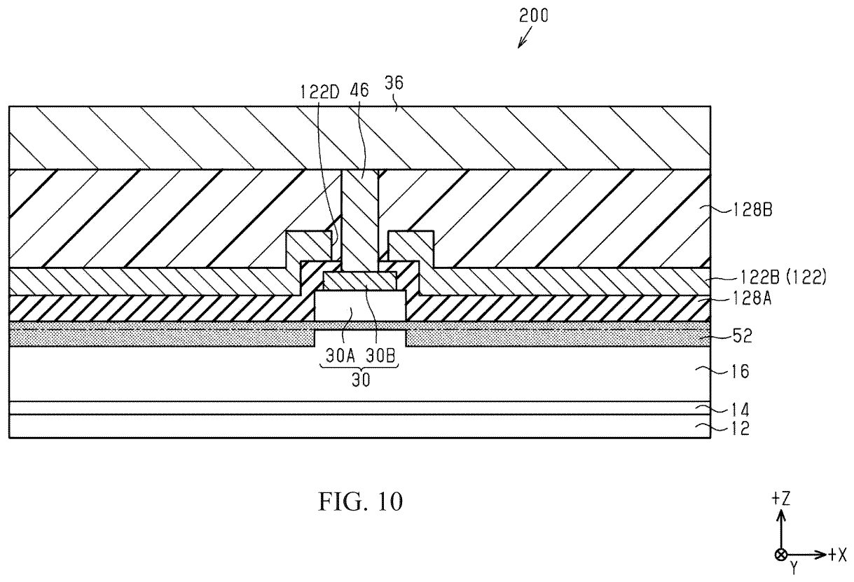

Referring to FIG. 6 to FIG. 10, a field effect transistor 200 according to the second embodiment is described below. FIG. 6 shows a brief plan view of the field effect transistor 200. FIG. 7 shows an enlarged partial plan view of the field effect transistor 200 in FIG. 6. FIG. 8 shows a schematic cross-sectional view along line F8-F8 in FIG. 7. FIG. 9 shows a schematic cross-sectional view along line F9-F9 in FIG. 6. FIG. 10 shows a schematic cross-sectional view along line F10-F10 in FIG. 7.

The second embodiment differs from the first embodiment in that, the configurations of the source electrodes 22, the drain electrodes 24 and the insulating layer 28 of the first embodiment are modified, and the remaining configuration details are the same as the first embodiment. Moreover, in the configuration of the second embodiment shown in FIG. 6 to FIG. 10, the same configurations are denoted by the same numerals as the first embodiment shown in FIG. 1 to FIG. 5. In the description below, associated details of the configurations common with those of the first embodiment are omitted for brevity, and only details of constituting elements different from those of the first embodiment are described.

### 2-1. Exemplary Cross-Sectional Structure of HEMT of Second Embodiment

As shown in FIG. 6 and FIG. 7, the field effect transistor 200 includes multiple transistors 110 each having a HEMT structure employing a nitride semiconductor. First of all, the HEMT structure of the unit transistor 110 of the second embodiment is described by focusing on differences from the first embodiment with reference to the section diagram of FIG. 8.

FIG. 8 shows an exemplary schematic cross-sectional view of the unit transistor 110 having a HEMT structure. The HEMT structure of each unit transistor 110 is the same as that of another. The HEMT structure is described by focusing on one unit 110; however, the description given is applicable to other unit transistors 110.

As shown in FIG. 8 to FIG. 10, the unit transistor 110 (the field effect transistor 200) of the second embodiment, in substitution for the source electrodes 22, the drain electrodes 4 and the insulating layer 28 (referring to FIG. 5) of the first embodiment, includes source electrodes 122, drain electrodes 124 and an insulating layer 128.

The insulating layer 128 includes a first insulating layer 128A and a second insulating layer 128B. The first insulating layer 128A is formed on the electron supply layer 18 to cover the gate structures 26. The first insulating layer 128A includes a source opening 128A1 and a drain opening 128A2. Moreover, the first insulating layer 128 further covers the gate connection portions 30 (referring to FIG. 10). The second insulating layer 128B is formed on the first insulating layer 128A to cover the source electrodes 122 and the drain electrodes 124.

Each of the first and second insulating layers 128A and 128B is a dielectric film, and is formed by any one single film of a silicon nitride (SiN) film, a silicon oxide (SiO₂) film, a silicon oxynitride (SiON) film, an aluminum oxide (Al₂O₃) film, an AlN film and an aluminum oxynitride (AlON) film, or a composite film formed by a combination including two or more of the above.

Each source electrode 122 includes a source electrode contact portion 122A embedded in the source opening 128A1 of the first insulating layer 128A and in contact with the electron supply layer 18, and a source electrode extension portion 122B formed on the first insulating layer 128A to cover the gate structures 26.

The source electrode extension portion 122B is integrally formed with the source electrodes 122A, covers the gate structures 26 and extends toward the drain electrodes 124. The source electrode extension portion 122B functions as a source field board, which alleviates concentration of an electric field generated at end portions of the gate structures 26 (the gate layer 26A and the gate electrodes 26B) near the drain electrodes 124.

The source electrode contact portion 122A is surrounded by each of the gate structures 26 in the plan view (referring to FIG. 6 and FIG. 7). Thus, the source electrode contact portion 122A can be regarded as a configuration corresponding to the source electrode 22 of the first embodiment. In other words, the source electrode 122 of the second embodiment can be regarded as a configuration in which the source electrode extension portion 122B is added to the source electrode 22 of the first embodiment. Moreover, the source electrode contact portion 122A is not necessarily interpreted as merely the part embedded into the source opening 128A1, but can also include the part protruding from the source opening 128A1.

Each drain electrode 124 includes a drain electrode contact portion 124A embedded in the drain opening 128A2 and in contact with the electron supply layer 18. Thus, the drain electrode contact portion 124A can be regarded as a configuration corresponding to the drain electrode 24 of the first embodiment. Moreover, the drain electrode contact portion 124A is not necessarily interpreted as merely the part embedded into the drain opening 128A2, but can also include the part protruding from the drain opening 128A2.

### 2-2. Exemplary Planar Layout of Field Effect Transistor of Second Embodiment

Next, primarily with reference to the plan views of FIG. 6 and FIG. 7 as well as with reference to the section diagrams of FIG. 8 to FIG. 10, an exemplary planar layout of the field effect transistor 200 is described by focusing on differences from the first embodiment. Moreover, for better understanding, the drawing of the insulating layer 128 (the first insulating layer 128A and the second insulating layer 128B) is omitted from FIG. 6 and FIG. 7. Moreover, in FIG. 6 and FIG. 7, single-dotted lines are used to represent an outer periphery of each of the source electrode 122 and the drain electrode 124.

In the example in FIG. 6, the field effect transistor 200 includes a total of six unit transistors 110 arranged in three rows along the X direction and in two columns along the Y direction. However, the number of the unit transistor 110 can be in a greater or smaller number. Each of the unit transistors 110 includes the source electrode contact portion 122A, the gate structure 26 (the gate layer 26A and the gate electrode 26B) surrounding the source electrode contact portion 122A, and the drain electrode contact portion 124A adjacent to the gate structure 26 on one side along the X direction. Moreover, in the example in FIG. 6, the unit transistor 110 located at on the rightmost along the X direction and the unit transistor 110 located on at the center along the X direction share the drain electrode contact portion 124A.

As shown in FIG. 6, the source electrode 122 can be formed to almost globally cover an element forming region (a region surrounded by the second high resistance region 54) of the field effect transistor 200 in the plan view. For example, the source electrode 122 has a shape integrally including multiple source electrode contact portions 122A and a source electrode extension portion 122B.

As shown in FIG. 7, the source electrode extension portion 122B includes a first opening 122C located at the drain electrode 124, and a second opening 122D located at the gate connection portion 30. Each of the drain electrodes 124 is located in the first opening 122C, and is surrounded by the source electrode extension portion 122B in the plan view. Moreover, as shown in FIG. 10, the gate connection conductor 46 connecting the gate electrode 30B of each gate connection portion 30 and the gate wiring 36 is located in the second opening 122D.

As shown in FIG. 6 and FIG. 7 the source electrode extension portion 122B includes an inter-drain extension region 122BX located above the first high resistance region 52 and between the adjacent drain electrodes 124 along the Y direction. The inter-drain extension region 122BX is equivalent to a region between adjacent first opening portions 122C along the Y direction.

As shown in FIG. 9, the inter-drain extension region 122BX is located on the first insulating layer 128A above the first high resistance region 52. The inter-drain extension region 122BX is formed to have a width WX less than or equal to the width WR1 of the first high resistance region 52 along the Y direction by a manner of being formed within a range of the first high resistance region 52 without going beyond the first high resistance region 52 along the Y direction. In the configuration above, since the inter-drain extension region 122BX is not located over the 2DEG 20 having equal potential as the drain electrode 124, a source-drain parasitic capacitance formed between the inter-drain extension region 122BX (that is, the drain electrode 122) and the 2DEG 20 having equal potential as the drain electrode 124 is reduced.

Moreover, the width WX of the inter-drain extension region 122BX can be set to be greater than the wiring width WG of the gate wiring 36. In other words, the wiring width WG of the gate wiring 36 can be set to be less than or equal to the width WX of the inter-drain extension region 122BX by a manner that the gate wiring 36 is formed within a range of the inter-drain extension region 122BX without going beyond the inter-drain extension region 122BX along the Y direction. Herein, as described above, when the width WX of the inter-drain extension region 122BX is less than or equal to the width WR1 of the first high resistance region 52, the wiring width WR of the gate wiring 36 becomes less than or equal to the width WR1 of the first high resistance region 52. In the configuration above, since the gate wiring 36 is not located above the 2DEG 20 having equal potential as the drain electrode 124, a gate-drain parasitic capacitance formed between the gate wiring 36 and the 2DEG 20 having equal potential as the drain electrode 124 is reduced.

As shown in FIG. 7, the drain opening 128A2 (that is, the drain electrode contact portion 124A embedded therein) is separated by a distance d3 from the first high resistance region 52 along the Y direction. Moreover, the drain opening 128A2 (the drain electrode contact portion 124A) is separated by a distance d4 from the gate structure 26 along the X direction. In this case, the distance d3 can be set to be greater than the distance d4. In the configuration above, an electric field applied between the drain electrode 124 and the first high resistance region 52 is smaller than an electric field applied between the drain electrode 124 and the gate structure 26. Accordingly, a decrease in a gate-drain withstand voltage caused by an electric field generated between the drain electrode 124 and the first high resistance region 52 is inhibited.

In addition to the advantages of the field effect transistor 100 of the first embodiment, the field effect transistor 200 of the second embodiment further provides the advantages below.

(2-1) The insulating layer 128 includes the first insulating layer 128A disposed on the electron supply layer 18. The source electrode 122 includes source electrode contact portion 122A embedded in the source opening 128A1 of the first insulating layer 128A and in contact with the electron supply layer 18. Moreover, the drain electrode 124 includes the drain electrode contact portion 124A embedded in the drain opening 128A2 of the first insulating layer 128A and in contact with the electron supply layer 18. According to the configuration above, for example, when the source electrode 122 and the drain electrode 124 are formed by means of dry etching, the first insulating layer 128A functions as an etch stop layer. Thus, damage of the electron supply layer 18 accompanied by forming of the source electrode 122 and the drain electrode 124 can be inhibited.

(2-2) The source electrode 122 includes the source electrode extension portion 122B, which is integrally formed with the multiple source electrode contact portions 122A, covers the multiple gate structures 26 and extends toward the multiple drain electrodes 124. According to the configuration above, the source electrode extension portion 122B functions as a source field board, which alleviates concentration of an electric field generated at end portions of the gate structures 26 (the gate layers 26A and the gate electrodes 26B) near the drain electrodes 124. Accordingly, the field effect transistor 200 with increased withstand voltage can be implemented without involving additional steps.

(2-3) Each of the drain electrodes 124 is surrounded by the source electrode extension portion 122B in the plan view. According to the configuration above, by surrounding a high potential generated in the drain electrode 124 by the source electrode extension portion 122B (that is, the source electrode 122), moisture resistance against the intrusion of moisture from around a chip can be improved.

(2-4) The source electrode extension portion 122B includes the inter-drain extension region 122BX located above the first high resistance region 52 and between the adjacent drain electrodes 124 along the Y direction. The inter-drain extension region 122BX is formed to have the width WX less than or equal to the width WR1 of the first high resistance region 52 along the Y direction. In the configuration above, the source-drain parasitic capacitance formed between the inter-drain extension region 122BX (that is, the source electrode 122) and the 2DEG 20 having equal potential as the drain electrode 124 can be reduced.

(2-5) The gate wiring 36 is located above the inter-drain extension region 122BX (that is the source electrode 122) with the second insulating layer 128B separating in between. According to the configuration above, the gate-drain parasitic capacitance formed between the gate wiring 36 and the 2DEG 20 having equal potential as the drain electrode 124 can be further reduced.

(2-6) Moreover, the wiring width WG of the gate wiring 36 is set to be less than or equal to the width WX of the inter-drain extension region (122BX). According to the configuration above, since the gate wiring 36 is not located above the 2DEG 20 having equal potential as the drain electrode 124, the gate-drain parasitic capacitance formed between the gate wiring 36 and the 2DEG 20 having equal potential as the drain electrode 124 can be further reduced.

(2-7) The distance d3 between the drain opening 128A2 (that is, the drain electrode contact portion 124A embedded therein) and the first high resistance region 52 along the Y direction is set to be greater than the distance d4 between the drain opening 128A2 (the drain electrode contact portion 124A) and the gate structure 26. According to the configuration above, a decrease in the gate-drain withstand voltage caused by an electric field generated between the drain electrode 124 and the first high resistance region 52 can be inhibited.

### FIRST APPLICATION EXAMPLE

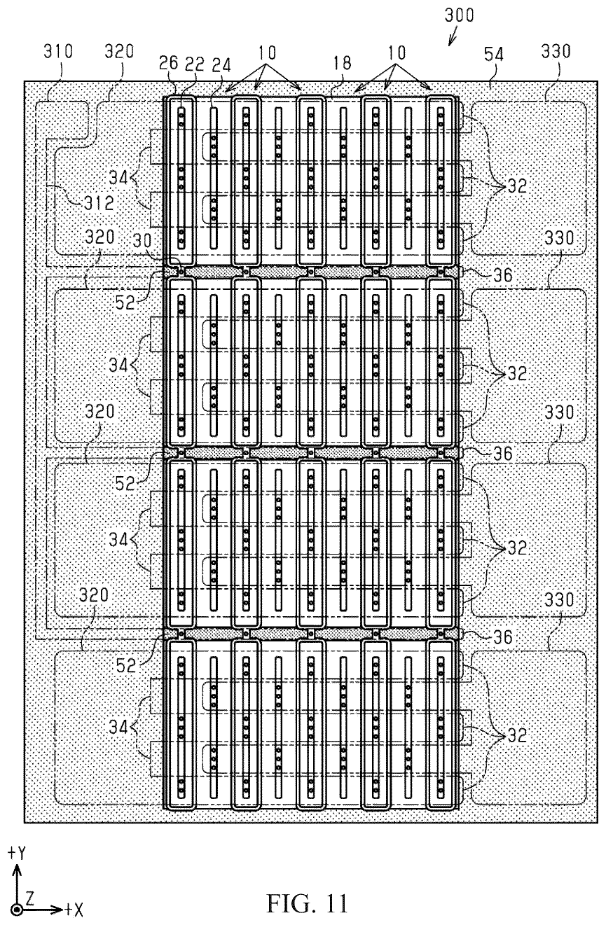

Referring to FIG. 11, a first application example of the field effect transistor 100 according to the first embodiment is described below. Moreover, an application of the field effect transistor 100 of the first embodiment is described herein; however, the same details are applicable to the field effect transistor 200 of the second embodiment.

As shown in FIG. 11, a field effect transistor 300 sets the number of the unit transistor 10 of the first embodiment is set to be four times, and includes a gate pad 310, a source pad 320 and a drain pad 330 as electrode pads. Thus, a field effect transistor with an even lower resistance can be implemented by means of increasing the number of the unit transistor 10. Moreover, the number of the unit transistor 10 can be set to a greater (or smaller) number according to a desired on-resistance.

The gate pad 310, the source pad 320 and the drain pad 330 are formed at positions different from the element forming region in which the multiple unit transistors 10 are formed, and are disposed above the second high resistance region 54. The gate pad 310, the source pad 320 and the drain pad 330 are formed in the same layer as the source wirings 32, the drain wirings 34 and the gate wiring 36 in the same step. Thus, no additional steps are resulted.

The gate wiring 36 located above the first high resistance region 52 is connected to the gate pad 310 via a gate wiring 312 (on the left of the drawing) to the gate pad 310. The source wirings 32 are connected to the source pad 320. The number of the source pad 320 is four in the first application example, and the source pad 320 located near the gate pad 310 has a shape different from the remaining source pads 320 without interfering the gate pad 310. Each gate wiring 36 is disposed between the adjacent source pads 320.

The drain wirings 34 are connected to the drain pad 330. The number of the drain pad 330 is four in the first application example; however, one single source pad can also be used. Since one single drain pad is used, a pad area is increased so that the number of bonding wires can be increased. As a result, conductive wire resistance and inductance are reduced. On the other hand, when multiple (four in the example shown) drain pads 330 are used as in the example in FIG. 11, a total drain pad area can be reduced, so that a parasitic capacitance generated between the drain pads 330 and the substrate 12 can be reduced.

### SECOND APPLICATION EXAMPLE

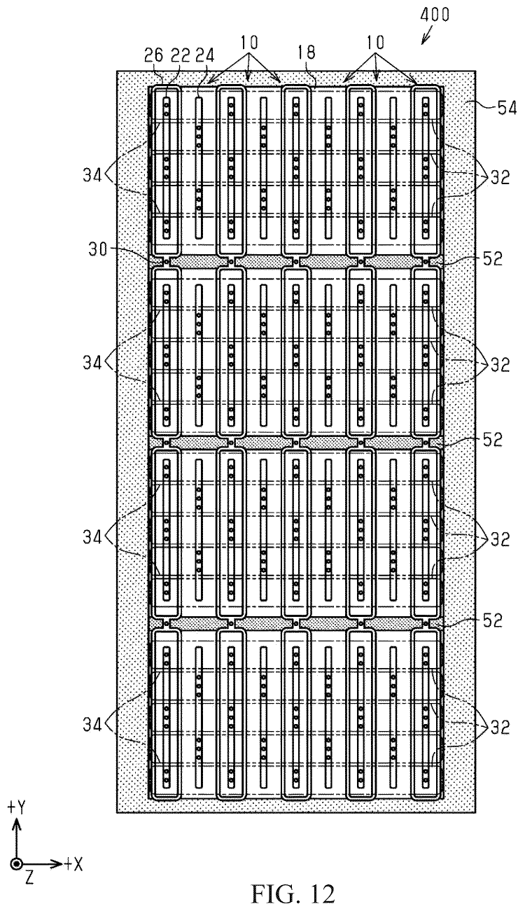

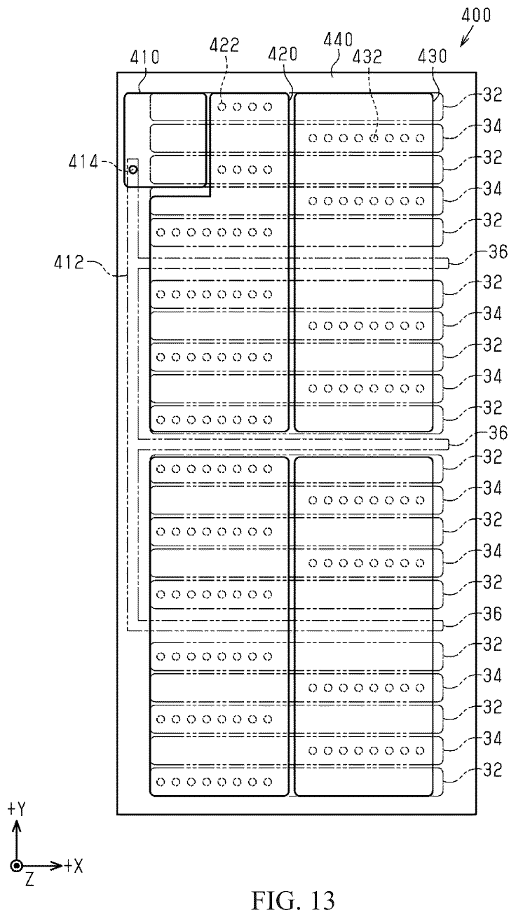

Referring to FIG. 12 and FIG. 13, a second application example of the field effect transistor 100 according to the first embodiment is described below. Moreover, an application of the field effect transistor 100 of the first embodiment is described herein; however, the same details are applicable to the field effect transistor 200 of the second embodiment.

As shown in FIG. 12 and FIG. 13, a field effect transistor 400 sets the number of the unit transistor 10 of the first embodiment is set to be four times, and includes a gate pad 410, a source pad 420 and a drain pad 430 as electrode pads. Moreover, for better understanding, the drawing of the electrode pads is omitted from FIG. 12. Thus, a field effect transistor with an even lower resistance can be implemented by means of increasing the number of the unit transistor 10. Moreover, the number of the unit transistor 10 can be set to a greater (or smaller) number according to a desired on-resistance.

The gate pad 410, the source pad 420 and the drain pad 430 are formed above the element forming region in which multiple unit transistors 10 are formed. The gate pad 410, the source pad 420 and the drain pad 430 are disposed on an insulating layer 440 (referring to FIG. 13) covering the source wirings 32, the drain wirings 34 and the gate wiring 36. In the configuration above, since a chip area is not increased by the electrode pads, chip costs can be suppressed.

As shown in FIG. 13, the gate wiring 36 located above the first high resistance region 52 is connected to a gate wiring 412 (on the left of the drawing) extending along the Y direction. The gate wiring 412 is connected to the gate pad 410 via a gate connection conductor 414 passing through the insulating layer 440.

The source wirings 32 are connected to the source pad 420 via a source connection conductor 422 passing through the insulating layer 440. The number of the source pad 420 is two in the second application example, and one source pad 420 located near the gate pad 410 has a shape different from the other source pad 420 without interfering the gate pad 410. With the shape adopted above, an increase in a chip area can be inhibited.

The drain wirings 34 are connected to the drain pad 430 via a drain connection conductor 432 passing through the insulating layer 440. The number of the drain pad 430 is two in the second application example. Moreover, in the second application example, the number of the source pad 420 and the number of the drain pad 430 are each set to two; however, they can each be set to one or three or more. Moreover, when the number of the source pad 420 and the number of the drain pad 430 are each set to two, the two source pads 420 and the two drain pads 430 can also be disposed at diagonal positions by means of modifying positions of the source connection conductor 422 and the drain connection conductor 432.

A plug formed of such as (W) can be used as a material for forming the gate connection conductor 42, the source connection conductor 422 and the drain connection conductor 432, or a same material as the gate pad 410, the source pad 420 and the drain pad 430 can also be used. When a plug is used, surface flatness of the gate pad 410, the source pad 420 and the drain pad 430 can be enhanced, thereby improving bonding properties of wire bonding.

The gate pad 410, the source pad 420 and the drain pad 430 can be formed of Al, Cu, Au or an alloy of Al and Cu. The insulating layer 440 can be formed of SiN and/or SiO₂, or an organic insulating film such as polyimide.

The embodiments can be modified as follows and be accordingly implemented as below. Moreover, the embodiments described above and the variation examples below can be implemented in combination, given that they are not technically contradictory.
The field effect transistor 100 in the various embodiments is not limited to employing GaN. For example, a nitride semiconductor such as AlN or InN can also be used in substitution for GaN.
The terms such as “on” used in the present application also includes meanings of “over” and “above”, unless otherwise specified in the context. Thus, the expression “a first layer formed on a second layer” can refer to that the first layer is in contact with the second layer and directly arranged on the second layer in some embodiments, or can refer to that the first layer is not in contact with the second layer and is arranged over or above the second layer. That is to say, the expression “on” does not eliminate a structure having another layer between the first layer and the second layer. For example, the various embodiments in which the electron supply layer 18 is formed on the electron transport layer 16 further include structures in which an intermediate layer is located between the electron supply layer 18 and the electron transport layer 16 in order to stabilize the 2DEG 20.

The Z-direction used in the present disclosure is not necessarily a vertical direction, and is not necessarily completely consistent with the vertical direction. Thus, in the various structures (for example, the structure shown in FIG. 1) in the present disclosure, “up” and “down” of the Z-direction given in the description are not limited to “up” and “down” of the vertical direction. For example, the X-axis direction can be the vertical direction, or the Y-axis direction can be the vertical direction.

The terms such as “vertical”, “horizontal”, “above/over”, “below/under”, “up”, “down”, “front”, “back”, “lateral”, “left”, “right”, “before” and “after” are directional terms depending on the specific orientation of a device in the description and the drawings. In the present disclosure, various orientations can be used in substitution, and thus these directional terms are not to be narrowly interpreted.

### Notes

The technical concepts that are conceivable based on the embodiments and the variation examples are recorded in the description below. Moreover, the reference numerals or symbols of the constituting elements of the embodiment corresponding to the constituting elements described in the notes are marked with parentheses. The numerals or symbols are used as examples for understanding purposes, and the constituting elements described in the notes are not to be limited to the constituting elements indicated by the numerals or symbols.

### Note 1

A field effect transistor (100; 200; 300; 400), comprising:
a substrate (12);
a first nitride semiconductor layer (16), disposed over the substrate (12);
a second nitride semiconductor layer (18), disposed on the first nitride semiconductor layer (16) and having a larger band gap than the first nitride semiconductor layer (16);
a plurality of source electrodes (22; 122A) on the second nitride semiconductor layer (18), respectively extending along a first direction, and arranged in parallel with each other along the first direction and a second direction perpendicular to the first direction in a plan view;
a plurality of drain electrodes (24; 124), on the second nitride semiconductor layer (18), respectively extending along the first direction, arranged in parallel with each other along the first direction and the second direction, and alternately arranged with the plurality of source electrodes (22; 122A) along the second direction;
a plurality of gate structures (26), on the second nitride semiconductor layer (18), respectively extending along the first direction, arranged in parallel with each other along the first direction and the second direction, and respectively surrounding one of the plurality of source electrodes (22; 122A) in the plan view, wherein each of the plurality of gate structures (26) includes a third nitride semiconductor layer (26A) disposed on the second nitride semiconductor layer (18), and a gate electrode (26B) disposed on the third nitride semiconductor layer (26A);
a first high resistance region (52), disposed in the first nitride semiconductor layer (16) and the second nitride semiconductor layer (18) and between the adjacent drain electrodes (24; 124) along the first direction;
a plurality of gate connection portions (30), respectively electrically connecting the adjacent gate structures (26) along the first direction;
a gate wiring (36), located above the first high resistance region (52), electrically connected to the plurality of gate connection portions (30) and extending along the second direction; and
an insulating layer (28; 128), covering the plurality of source electrodes (22; 122A), the plurality of drain electrodes (24; 124), the plurality of gate structures (26) and the plurality of gate connection portions (30), wherein the insulating layer (28; 128) is disposed between the gate wiring (36) and the first high resistance region (52).

### Note 2

The field effect transistor (100; 200; 300; 400) according to note 1, wherein a wiring width (WG) of the gate wiring (36) along the first direction is less than or equal to a width (WR1) of the first high resistance region (52) along the first direction.

### Note 3

The field effect transistor (100; 200; 300; 400) according to note 1 or 2, further comprising:
a second high resistance region (54), surrounding the plurality of source electrodes (22; 122A), the plurality of drain electrodes (24; 124) and the plurality of gate structures (26) in the plan view, and disposed in the first nitride semiconductor layer (16) and the second nitride semiconductor layer (18),
wherein the second high resistance region (54) is connected to the first high resistance region (52).

### Note 4

The field effect transistor (100; 200; 300; 400) according to note 3, wherein
each of the plurality of drain electrodes (24; 124) is surrounded by the first high resistance region (52) adjacent to one side along the first direction, the second high resistance region (54) adjacent to the other side along the first direction and the gate structure (26) adjacent to both sides along the second direction, or surrounded by the first high resistance region (52) adjacent to both sides along the first direction and the gate structure (26) adjacent to both sides along the second direction.

### Note 5

The field effect transistor (100; 200; 300; 400) according to any one of notes 1 to 4, wherein a distance (d1; d3) between the drain electrode (24; 124) and the first high resistance region (52) along the first direction is greater than a distance (d2; d4) between the drain electrode (24; 124) and the gate structure (26) along the second direction.

### Note 6

The field effect transistor (200; 300; 400) according to any one of notes 1 to 5, wherein the insulating layer (128) includes a first insulating layer (128A) disposed on the second nitride semiconductor layer (18), each of the plurality of source electrodes (122A) includes a source electrode contact portion (128A) embedded in a source opening (128A1) of the first insulating layer (128A) and in contact with the second nitride semiconductor layer (18), and each of the plurality of drain electrodes (124) includes a drain electrode contact portion (124A) embedded in a drain opening (128A2) of the first insulating layer (128A) and in contact with the second nitride semiconductor layer (18).

### Note 7

The field effect transistor (100; 200; 300; 400) according to any one of notes 1 to 6, further comprising:
a source electrode extension portion (122B), integrally formed with the plurality of source electrodes (122A), covering the plurality of gate structures (26) and extending toward the plurality of drain electrodes (124).

### Note 8

The field effect transistor (200; 300; 400) according to any one of notes 1 to 6, wherein each of the plurality of drain electrodes (124) is surrounded by the source electrode extension portion (122B) in the plan view.

### Note 9

The field effect transistor (200; 300; 400) according to note 8, wherein the source electrode extension portion (122B) includes an inter-drain extension region (122BX) located above the first high resistance region (52) and between the adjacent drain electrodes (124) along the first direction, and a width (WX) of the inter-drain extension region (122BX) along the first direction is less than or equal to a width (WR1) of the first high resistance region (52) along the first direction.

### Note 10

The field effect transistor (200; 300; 400) according to note 6, further comprising:
a source electrode extension portion (122B), integrally formed with the plurality of source electrodes (122A), covering the plurality of gate structures (26) and extending toward the plurality of drain electrodes (124); and
the source electrode extension portion (122B) includes an inter-drain extension region (122BX) located above the first high resistance region (52) and between the adjacent drain electrodes (124) along the first direction;
wherein the insulating layer (128) includes:
   a second insulating layer (128B) disposed on the first insulating layer (128A), and located between the gate wiring (36) and the inter-drain extension region (122BX),
   a width (WX) of the inter-drain extension region (122BX) along the first direction is less than or equal to a width (WR1) of the first high resistance region (52) along the first direction;
   a wiring width (WG) of the gate wiring (36) along the first direction is less than or equal to a width (WX) of the inter-drain extension region (122BX) along the first direction.

### Note 11

The field effect transistor (200; 300; 400) according to any one of notes 6 to 10, wherein a distance (d3) between the drain opening (128A2) and the first high resistance region (52) along the first direction is greater than a distance (d4) between the drain opening (128A2) and the gate structure (26) along the second direction.

### Note 12

The field effect transistor (100; 200; 300; 400) according to any one of notes 1 to 10, further comprising:
a source wiring (32), extending along the second direction and electrically connected to the plurality of source electrodes (22; 122A); and
a drain wiring (34), extending along the second direction and electrically connected to the plurality of drain electrodes (24; 124), wherein the gate wiring (36), the source wiring (32) and the drain wiring (34) are arranged on the insulating layer (28; 128).

### Note 13

The field effect transistor (100; 200; 300; 400) according to note 12, wherein the gate wiring (36) is adjacent to the source wiring (32) along the first direction.

### Note 14

The field effect transistor (100; 200; 300; 400) according to note 12 or 13, wherein a wiring width (WG) of the gate wiring (36) along the first direction is less than or equal to a wiring width (WS) of the source wiring (32) along the first direction, and less than or equal to a wiring width (WD) of the drain wiring (34) along the first direction.

### Note 15

The field effect transistor (100; 200; 300; 400) according to any one of notes 1 to 14, wherein the first high resistance region (52) includes an impurity that forms a region having a higher resistance than a two-dimensional electron gas (20) channel region formed in the first nitride semiconductor layer.

### Note 16

The field effect transistor (100; 200; 300; 400) according to note 15, wherein the first high resistance region (52) includes the impurity introduced by ion implantation.

### Note 17

The field effect transistor (100; 200; 300; 400) according to note 15 or 16, wherein the impurity is at least one of He, B, N, O, F, and Ar.

### Note 18

The field effect transistor (100; 200; 300; 400) according to note 3 or 4, wherein the second high resistance region (54) includes an impurity that forms a region having a higher resistance than a two-dimensional electron gas (20) channel region formed in the first nitride semiconductor layer.

### Note 19

The field effect transistor (100; 200; 300; 400) according to note 18, wherein the second high resistance region (54) includes the impurity introduced by ion implantation.

### Note 20

The field effect transistor (100; 200; 300; 400) according to note 18 or 19, wherein the impurity is at least one of He, B, N, O, F, and Ar.

### Note 21

The field effect transistor (100; 200; 300; 400) according to any one of notes 1 to 20, wherein the third nitride semiconductor layer (26A) includes acceptor type impurities.

### Note 22

The field effect transistor (100; 200; 300; 400) according to any one of notes 1 to 21, wherein the gate electrode (26B) is formed of a metal that forms a Schottky junction with the third nitride semiconductor layer (26A).

### Note 23

The field effect transistor (100; 200; 300; 400) according to note 22, wherein the metal is at least one of TiN, WSi, and WSiN.

It should be noted that the description above are for illustrative and exemplary purposes. It can be conceivable to a person skilled in the art that, apart from the enumerated constituting elements and methods (manufacturing processes) for the purpose of describing the technical details of the present disclosure, there are many other conceivable combinations and substitutions. The present disclosure is intended to encompass all substitutions, modifications and variations covered by the scope of claims of the present disclosure.

1. A field effect transistor, comprising:
a substrate;
a first nitride semiconductor layer, disposed over the substrate;
a second nitride semiconductor layer, disposed on the first nitride semiconductor layer and having a larger band gap than the first nitride semiconductor layer;
a plurality of source electrodes on the second nitride semiconductor layer, respectively extending along a first direction, and arranged in parallel with each other along the first direction and a second direction perpendicular to the first direction in a plan view;
a plurality of drain electrodes, on the second nitride semiconductor layer, respectively extending along the first direction, arranged in parallel with each other along the first direction and the second direction, and alternately arranged with the plurality of source electrodes along the second direction;
a plurality of gate structures, on the second nitride semiconductor layer, respectively extending along the first direction, arranged in parallel with each other along the first direction and the second direction, and respectively surrounding one of the plurality of source electrodes in the plan view, wherein each of the plurality of gate structures includes:
a third nitride semiconductor layer disposed on the second nitride semiconductor layer; and
a gate electrode disposed on the third nitride semiconductor layer,
a first high resistance region, disposed in the first nitride semiconductor layer and the second nitride semiconductor layer and between the adjacent drain electrodes along the first direction;
a plurality of gate connection portions, respectively electrically connecting the adjacent gate structures along the first direction;
a gate wiring, located above the first high resistance region, electrically connected to the plurality of gate connection portions and extending along the second direction; and
an insulating layer, covering the plurality of source electrodes, the plurality of drain electrodes, the plurality of gate structures and the plurality of gate connection portions, wherein the insulating layer is disposed between the gate wiring and the first high resistance region.

2. The field effect transistor of claim 1, wherein a wiring width of the gate wiring along the first direction is less than or equal to a width of the first high resistance region along the first direction.

3. The field effect transistor of claim 1, further comprising:
a second high resistance region, surrounding the plurality of source electrodes, the plurality of drain electrodes and the plurality of gate structures in the plan view, and disposed in the first nitride semiconductor layer and the second nitride semiconductor layer.

4. The field effect transistor of claim 3, wherein each of the plurality of drain electrodes is
surrounded by the first high resistance region adjacent to one side along the first direction, the second high resistance region adjacent to the other side along the first direction and the gate structure adjacent to both sides along the second direction, or
surrounded by the first high resistance region adjacent to both sides along the first direction and the gate structure adjacent to both sides along the second direction.

5. The field effect transistor of claim 1, wherein a distance between the drain electrode and the first high resistance region along the first direction is greater than a distance between the drain electrode and the gate structure along the second direction.

6. The field effect transistor of claim 1, wherein
the insulating layer includes a first insulating layer disposed on the second nitride semiconductor layer,
each of the plurality of source electrodes includes a source electrode contact portion embedded in a source opening of the first insulating layer and in contact with the second nitride semiconductor layer, and
each of the plurality of drain electrodes includes a drain electrode contact portion embedded in a drain opening of the first insulating layer and in contact with the second nitride semiconductor layer.

7. The field effect transistor of claim 1, further comprising:
a source electrode extension portion, integrally formed with the plurality of source electrodes, covering the plurality of gate structures and extending toward the plurality of drain electrodes.

8. The field effect transistor of claim 7, wherein each of the plurality of drain electrodes is surrounded by the source electrode extension portion in the plan view.

9. The field effect transistor of claim 8, wherein
the source electrode extension portion includes an inter-drain extension region located above the first high resistance region and between the adjacent drain electrodes along the first direction, and
a width of the inter-drain extension region along the first direction is less than or equal to a width of the first high resistance region along the first direction.

10. The field effect transistor of claim 6, further comprising:
a source electrode extension portion, integrally formed with the plurality of source electrodes, covering the plurality of gate structures and extending toward the plurality of drain electrodes, wherein
the source electrode extension portion includes an inter-drain extension region located above the first high resistance region and between the adjacent drain electrodes along the first direction,
the insulating layer includes a second insulating layer disposed on the first insulating layer, and located between the gate wiring and the inter-drain extension region,
a width of the inter-drain extension region along the first direction is less than or equal to a width of the first high resistance region along the first direction, and
a wiring width of the gate wiring along the first direction is less than or equal to a width of the inter-drain extension region along the first direction.

11. The field effect transistor of claim 6, wherein a distance between the drain opening and the first high resistance region along the first direction is greater than a distance between the drain opening and the gate structure along the second direction.

12. The field effect transistor of claim 1, further comprising:
a source wiring, extending along the second direction and electrically connected to the plurality of source electrodes; and
a drain wiring, extending along the second direction and electrically connected to the plurality of drain electrodes, wherein
the gate wiring, the source wiring and the drain wiring are arranged on the insulating layer.

13. The field effect transistor of claim 12, wherein the gate wiring is adjacent to the source wiring along the first direction.

14. The field effect transistor of claim 12, wherein
a wiring width of the gate wiring along the first direction is
less than a wiring width of the source wiring along the first direction, and
less than a wiring width of the drain wiring along the first direction.

15. The field effect transistor of claim 1, wherein the first high resistance region includes an impurity that forms a region having a higher resistance than a two-dimensional electron gas channel region formed in the first nitride semiconductor layer.

16. The field effect transistor of claim 15, wherein the first high resistance region includes the impurity introduced by ion implantation.

17. The field effect transistor of claim 15, wherein the impurity is at least one of He, B, N, O, F, and Ar.

18. The field effect transistor of claim 1, wherein the third nitride semiconductor layer includes acceptor type impurities.

19. The field effect transistor of claim 1, wherein the gate electrode is formed of a metal that forms a Schottky junction with the third nitride semiconductor layer.

20. The field effect transistor of claim 19, wherein the metal is at least one of TiN, WSi, and WSiN.
